(19) United States
(12) Patent Application Publication
(10) Pub. No.: US 2011/0079281 A1
(43) Pub. Date: Apr. 7, 2011

(54) PHOTOVOLTAIC SOLAR CELL AND METHOD OF PRODUCTION THEREOF

(75) Inventors: Michael Reuter, Stuttgart (DE); Rainer Merz, Ludwigsburg (DE); Johannes Rostan, Stuttgart (DE)

(73) Assignee: Universitat Stuttgart, Stuttgart (DE)

(21) Appl. No.: 12/935,814

(22) PCT Filed: Apr. 2, 2009
(86) PCT No.: PCT/EP2009/002433

§ 371 Date: Dec. 22, 2010

(30) Foreign Application Priority Data
Apr. 4, 2008 (DE) 10 2008 017 312.6

(51) Int. Cl. H01L 31/0224; H01L 31/18

(52) U.S. Cl. 136/256; 438/96; 257/E31.124

(57) ABSTRACT

A solar cell comprising a base layer of p-doped silicon and an emitter layer of n-doped silicon, where an electrode is arranged regionally on the emitter layer and optionally it passivation layer is arranged regionally on the back surface of the base layer and a layer of a dielectric, the entire area of which is covered with a metal layer, is arranged regionally thereon, where the metal layer is in electrically conducting contact via an interlayer with the base layer over the regions not covered by the layer of dielectric and the interlayer comprises a mixed phase from the material of the passivation layer and the material of the metal layer. The present invention further relates to a method of production of said solar cell.

The present invention relates to a photovoltaic solar cell with an all-over passivated back surface with point metal contacts and a method of production thereof.

Photovoltaic solar cells have been at the centre of interest of research and development for some time, in particular on account of various government promotion schemes in many countries based on the increasing cut-backs in the use of fossil raw materials for electricity generation and based on ecological aspects of electric power generation.

Solar cells consist typically of single-crystalline or polycrystalline silicon, i.e. typically of a layer (base layer) of a p-doped silicon and a layer of an n-doped silicon (emitter layer), and at present—owing to the high costs of materials—the aim is to make silicon solar cells as thin as possible. Silicon solar cells currently manufactured typically have a cell thickness W of approx. 220 μm. Thinner cell thicknesses mean that said solar cells are mechanically very delicate.

Solar cells typically have a front contact and a back contact, which for example can be produced by screen printing (M. A. Green, “Photovoltaics: Technology Overview”, Energy Policy 2000; 28-14, p. 989-998).

Typically, the front and/or back of the solar cell are in addition texturized, for better coupling of light into the cell (see for example DE 10352423 B3). Passivation with silicon nitride (SiNₓ:H) then reduces recombination losses on the front and acts simultaneously as an antireflection film.

The front contact is typically in the form of a fine network, which is obtained for example by screen printing from a metal-containing, and in particular a silver-containing paste and, after a heat treatment, thus makes contact with the diffused emitter through the SiNₓ:H.

The back surface contact of the solar cell is usually provided by a layer of aluminium, applied by screen printing. This can for example also be achieved with an aluminium-containing paste, which is applied to the solar cell, with subsequent heat treatment forming an aluminium silicide on the interface, which on the one hand is responsible for good ohmic contact at the aluminium/silicon interface, and in addition produces an electric field (back surface field, BSF), which arises through band bending due to the alloying. In particular the BSF helps to reduce the recombination losses on the back surface of the solar cell.

However, an all-over back surface contact is not physically optimal, since the recombination rate of the photogenerated charge carriers and thus the measure for the inverse quality on an all-over metal contact is higher by approximately three orders of magnitude, relative to a fully passivated surface. The usual all-over metallization of the back surface therefore limits the efficiency of existing solar cells.

In order to improve the efficiency, attempts were therefore made to minimize the local contacting of the back surface and thus limitation of the area with high recombination properties and charge carrier collection.

For example, the use of photolithographic methods, as described for example by Wang et al. in Appl. Phys. Lett. 1990, 57, 602 and by Blakers et al. in Proceedings 9th Euro, PVSEC, Freiburg, Germany 1989, p. 32, offers a possible means for point localization of contacts. However, photolithography is a slow and expensive process and typically is therefore unsuitable for industrial production.

Further possibilities for improving the back surface recombination rate were proposed by Jensen et al., Prog. Photovolt: Res. Appl. 2002, 10, p. 1-13 (so-called “Heterotransition”) or by E. Schneiderlöchner et al. by means of laser-fired point contacts (Progr. Photovoltaics: Research and Applications 2002, 10, p. 29-34, and DE 10046170 A1).

Yet other possibilities for production of point contacts on the back surface of solar cells are disclosed in DE 10101375 A1, according to which a solution containing a metal compound is applied in points on the back surface of the solar cell and is then reduced, so that metallic point contacts form on the surface.

Furthermore, DE 102004046554 discloses a method for the production of point contacts by additional application of mineral or organic binders containing light reflecting particles on the interface between an additional passivation layer and a metallic contact layer on the back surface of a solar cell.

Another approach to point contacts is described in DE 60121161 T2, with additional application of a light-scattering layer on the back surface of the solar cell, consisting of particles agglomerated with a binder, wherein the particles display a contrast attenuation of over 40%.

WO 00/22681 teaches the use of a melt-through process to restore contact between the metallic back-surface contact layer and the silicon (emission) layer, which is said to be achieved by etching grooves into the layered material.

However, all the existing methods known from the state of the art are expensive and are extremely difficult to implement both from the standpoint of process technology and from the standpoint of cost.

The problem facing the present invention was therefore to provide a solar cell that has point contacts between the back surface electrode (the back surface contact) and the silicon base layer.

This problem is solved according to the invention by a solar cell which has a base layer of p-doped silicon and an emitter layer of n-doped silicon, with an electrode arranged regionally on the emitter layer and a layer of a dielectric arranged regionally on the back surface of the base layer, wherein the entire area of the layer of dielectric is covered by a metal layer and wherein said metal layer, on the regions not covered by the dielectric, is in electrically conducting connection with the base layer through an interlayer and the interlayer consists of a mixed phase of the material of the base layer and the material of the metal layer.

This structure of the solar cell according to the invention produces a point contact between the material of the metal layer and of the base layer, resulting in a new regularly or irregularly arranged point back contact with low recombination rate of the charge carriers and improving the efficiency of the solar cells according to the invention by several percentage points compared with conventional solar cells of the state of the art. Commercially available solar cells have at present an efficiency of approx. 16-18%, whereas the solar cell according to the invention reaches values of approx. 19-20%.

In preferred embodiments of the solar cell according to the invention it is further provided that the back surface of the base layer is covered regionally by a passivation layer, on which the dielectric layer is then applied regionally. In this case the interlayer forming an ohmic contact consists of a mixed phase of the materials of the base layer, of the passivation layer and of the metal layer.

The diameter of the point contacts is between 100 nm and 1 mm. The diameter depends in particular on the starting material of the covering and the layer thicknesses. Typical values, for a covering of 1%, are 10-20 μm.

The coverage, i.e. the area of the point contacts of the interlayer relative to the total area, is according to the invention between 0.1 and 2%, preferably between 0.5 and 1.5%.

The solar cell according to the invention displays a higher open-circuit voltage than would be reached for example using an all-over metal contact. Thus, the open-circuit voltage increases, relative to a solar cell with all-over metal contact, from 630 mV to 650 mV.

Typically the dielectric consists of silicon nitride or silicon dioxide, wherein silicon nitride is particularly preferred, since silicon nitride improves the optical properties of the dielectric, which acts as a back-surface reflector (W. Brendle, Thesis, Universität Stuttgart [2007]).

Furthermore, the use of SiO₂ or silicon nitride (SiNₓ:H) reduces the absorption losses of radiant energy in the aluminium back contact.

Typically the silicon nitride also contains hydrogen, so that a layer thickness of 100 nm is obtained at a refractive index n of about 1.9 and a wavelength of λ=632.8 nm as optical back-surface reflector of high efficiency. Furthermore, the SiNₓ:H protects any sensitive passivating layer of amorphous silicon, if present.

Silicon nitride SiNₓ:H is produced by varying the process gases during the PECVD process, nitrogen and ammonia, wherein its refractive index is adjustable by appropriate choice of the gas flow conditions in the range from n˜1.8 (λ=632.8 nm) for low-silicon layers up to n=3.8 (λ=632.8 nm) for pure amorphous silicon layers.

In a preferred embodiment of the invention, as already mentioned above, in addition a so-called passivation layer is arranged between the dielectric and the base layer. Preferably this passivation layer consists of (intrinsically) amorphous silicon (a-Si:H or i-a-Si:H), and in particular the use of the layer combination a-Si:H/SiNₓH in the back surface structure of the solar cell according to the invention improves the SiO₂ back surfaces usually employed by approx. 10% with respect to efficiency and reflectivity.

The advantage in using amorphous silicon (a-Si:H) is that it permits substantially lower deposition temperatures in the PECVD process than for example with the existing SiO₂ or SiOCₓ, so that back surface recombination rates S of ≦10 cm·s⁻¹ could be achieved in a temperature range of 200° C.≦Tₚ≦250° C. (Tₚ=process temperature). Moreover, an a-Si:H layer means that solar cells according to the invention can reach a recombination rate S<100 cm·s⁻¹, if the a-Si:H layer was deposited at a process temperature Tₚ of about 110 degrees and was then annealed at a temperature of 200° C. for a period of several minutes.

Passivation with amorphous silicon is, according to the invention, a condition for low process temperatures with acceptable surface recombination rates.

In particular the combination of silicon nitride and the passivation layer of a-Si:H permits a further decrease in cell thickness of the solar cell to below 200 μm, wherein a preferred base thickness of the solar cell according to the invention has a thickness of W<50 μm.

The material of the metal layer preferably contains aluminium or an aluminium alloy, e.g. an aluminium/silver alloy etc., which can for example be applied simply in paste form by screen printing and is capable of forming electrically conducting alloys with silicon (silicides).

The metal layer of aluminium, i.e. the vapour-deposited metal back contact, forms the back surface of the a-Si:H/SiNₓ:H back surface structure and has a thickness of approx. 2 μm.

Therefore the material of the interlayer is preferably an aluminium-silicon alloy, which produces the point contact between the metal layer, i.e. for the back surface electrode of aluminium and the base layer.

Owing to the back surface passivation according to the invention, the solar cell according to the invention has an especially high efficiency of approx. 19-20% and improved light trapping because of a better back-surface reflector.

The problem facing the present invention is further solved by a simple and easily industrially implemented method for production of a solar cell according to the invention, comprising the steps of
a) applying discrete particles on the base layer of a semiconductor surface forming a solar cell
b) depositing a layer of a dielectric on the regions of the base layer not covered by the particles
c) removing the particles
d) depositing a metal layer on the dielectric
e) producing an ohmic contact between the base layer and the metal layer.

Optionally the method comprises, before step a), the further step of applying a passivation layer on the base layer of the semiconductor surface forming a solar cell.

Either without or after passivation of the surface of the base layer with preferably intrinsically amorphous silicon (i-a-si:H), discrete particles, in particular particles of silicon dioxide, are applied on the passivation layer, which serve as a “marker” for the point contacts that are to be formed.

Said particles preferably have a monomodal size distribution, so that the point contacts produced are of a substantially uniform size.

Now it is possible to apply the silicon dioxide particles either regularly or irregularly, so that any kinds of individually selected arrays of point contacts can be produced. The preferred distance of the resultant point contacts from one another is approx. 1 mm, wherein a coverage of approx. 1% is intended.

After applying the silicon dioxide particles on the base layer or on the passivation layer, the dielectric is deposited thereon by per se known processes, for example by PECVD processes etc., wherein any desired contact structures is possible by varying the grain size and arrangement.

Apart from PECVD (plasma enhanced chemical vapour deposition), in addition the so-called HWCVD (hot wire chemical vapour deposition) process, IAD (ion assisted deposition), PVD (physical vapour deposition) etc. processes can be used according to the invention.

Preferably, with a PVD or IAD process it is also possible to coat the regions in shadow under the particles, whereas the regions in shadow are not coated in the PECVD process, so that larger point contacts are formed at identical particle size, depending on which process is used.

The material used for the particles, preferably SiO₂-quartz particles, is cheap, non-toxic and in particular there is no risk of contaminating the equipment for solar cell production, for which high purity is essential.

The size of the point contacts is determined by the size of the particles, which are typically used in the range from 100 nm to 1 mm, wherein the number and the pattern of the point contacts per surface can always be adjusted exactly as required by means of laying-on devices (e.g. structured thickness).

In step d) of the method according to the invention, the particles are easily removed, for example by applying mechanical energy such as by jolting, shaking, tapping, or with a blast or current of air etc.

Then a metal layer, preferably an aluminium layer, for example with a layer thickness of 10 to 50 μm, preferably in the range from 20 to 23 μm, is deposited on the dielectric. Through the particle overlay regions previously coated by the grains, first there is formation of contact between the base layer or passivation layer and the metal layer of aluminium. The metal layer is either vapour-deposited, wherein thicknesses of approx. 2 μm are obtained, or is printed on by screen printing, with a thickness of approx. 20 μm.

Then the metal layer is sintered, with the result that, in the contact region between the base layer or the passivation layer and the metal layer, an interlayer of an alloy between the amorphous silicon and the metal is formed, providing electrical contact of the base layer optionally arranged under the passivation layer, i.e. an ohmic contact is produced. The thickness of this point “interlayer” is approx. 2-5 μm, and wherein a decreasing gradient of the Si distribution from the base layer outwards is to be observed.

The invention is further explained on the basis of drawings, though these are not to be regarded as limiting.

There are shown in:

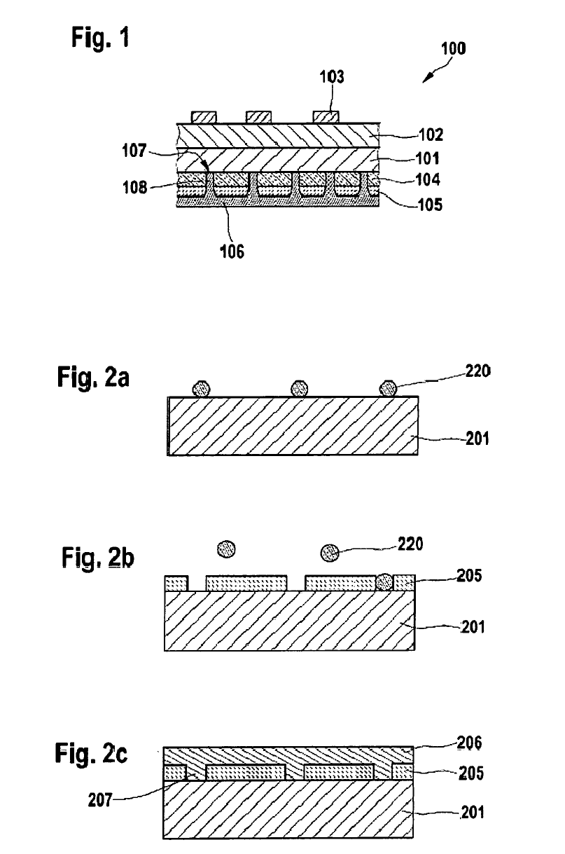

FIG. 1 a schematic cross-section through a solar cell according to the invention

FIG. 2 a schematic diagram of the method according to the invention

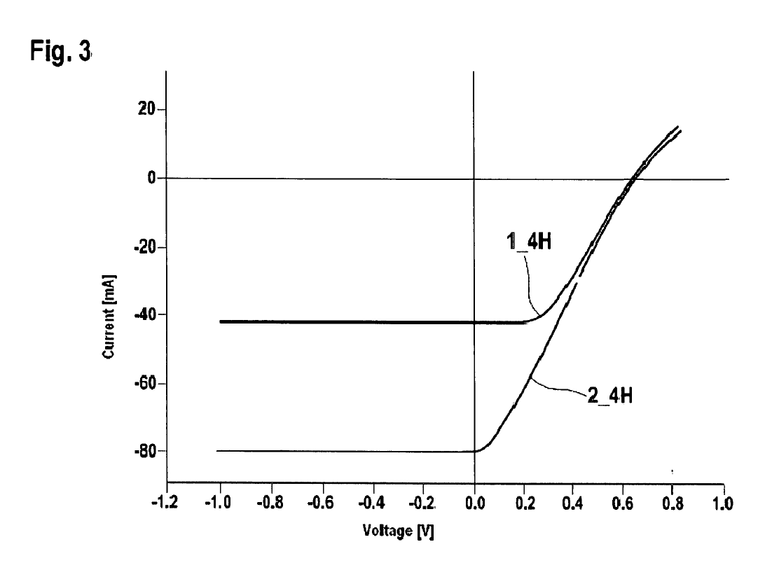

FIG. 3 the current-voltage characteristic curve of a solar cell according to the invention

A solar cell according to the invention 100 is shown schematically in FIG. 1. The solar cell 100 comprises a base layer 101 of p-doped silicon and an emitter layer 102 of n-doped silicon. An electrode 103, consisting for example of aluminium or silver, is arranged regionally on the emitter layer 102. A passivation layer 104 is arranged regionally on the back surface of the base layer 101. The passivation layer consists for example of a-Si:H (see Plagwitz et al., Progr. Photovolt. Res. Appl. 2004, 12, p. 47-54). Above that there is a layer 105 of a dielectric, which has flat, point regions 107, in which the layer of dielectric 105 is interrupted. The dielectric is preferably silicon nitride or in less preferred embodiments of the present invention silicon dioxide. Preferably, as already explained, the silicon nitride contains approx. 5-10% hydrogen, which can be achieved by suitable deposition processes, including for example the use of PECVD processes. The combination of materials of the passivation layer and the dielectric leads to excellent back surface passivation and high light trapping with low recombination rates.

On the dielectric layer 105 of silicon nitride there is an approx. 10 to 20 μm thick layer 106 of aluminium, which was deposited either by screen printing or by vapour deposition. Via an approx. 2-5 μm thick interlayer 108, the aluminium is in electrically conducting contact with the base layer 101, which is formed from a-Si:H in the thermal sintering of the deposited aluminium with the defined regions of the passivation layer. The size of the contact, i.e. the diameter of interlayer 108, is typically of the order of 2 μm to 1 mm. The form of the interlayer 108 can thus also be described as “cylindrical”.

The solar cell according to the invention then makes it possible to lower the metallization ratio on the back surface of the base layer 101 from 100% to approx. 1%, which leads to a decrease of electronically poor areas (recombination centres), and to a decrease in optical losses on the back surface through improvement of the back-surface reflector. In addition, the electronic quality of the back surface is increased.

FIG. 2 shows a schematic diagram of the method according to the invention, where in a first step (FIG. 2a) a silicon wafer with or without a passivation layer is covered with silicon dioxide particles, wherein it is possible for the covering to take place in a regular or irregular arrangement.

Then, for example by means of PECVD (FIG. 2b), a layer of a dielectric, e.g. SiN, as described above, is deposited for example by PECVD or HWCVD processes, wherein the regions around the particles are covered in a PECVD process with the layer of dielectric 205. As already explained previously, depending on the coating process it is also possible to coat the regions in shadow under the particles, which leads to a further decrease in contact area.

Then the particles 220 are removed by mechanical action, for example by jolting or shaking, and then a metal contact 206 (FIG. 2c) is deposited by per se known processes, forming point contacts between the metal contacts and the silicon wafer. After sintering at approx. 300-700° C. there is formation of the electrically conductive interlayer 207.

The method according to the invention can be carried out simply and inexpensively, in particular because quartz particles of high purity and quality are also available at low cost and, moreover, can be obtained in a large number of discrete sizes and monomodal particle size distributions.

An additional improvement of the adherence of the silicon dioxide particles (masking particles) on the silicon layer or passivation layer is not necessary according to the invention, because in step b) of the method according to the invention the physicochemical adherence due to the electrostatic charge of the particles on the surface is sufficient for the subsequent coating step to be carried out.

FIG. 3 shows the current-voltage characteristic curve of a solar cell according to the invention with the back contact obtained according to the invention. The cells according to the present invention have a higher open-circuit voltage than would be possible with an all-over back contact. Cell 2_4 has an open-circuit voltage V_{oc}=652 mV and cell 1_4 has an open-circuit voltage V_{oc}=646 mV, whereas a cell with an all-over metal contact reaches a maximum open-circuit voltage V_{oc} of 630 mV.

1. A solar cell comprising a base layer of p-doped silicon and an emitter layer of n-doped silicon, with an electrode arranged regionally on the emitter layer and, arranged regionally on a back surface of the base layer, a layer of a dielectric, which is covered on its entire surface by a metal layer and where the metal layer is in electrically conducting contact via an interlayer with the base layer over the regions not covered by the layer of dielectric, and the interlayer comprises a mixed phase from the material of the base layer and the material of the metal layer.

2. The solar cell according to claim 1, wherein a passivation layer is arranged regionally between the back surface of the base layer and the layer of dielectric.

3. The solar cell according to claim 2, wherein the interlayer comprises mixed phase from the material of the base layer and the material of the metal layer and/or the passivation layer.

4. The solar cell according to claim 3, wherein the dielectric is silicon nitride or silicon dioxide.

5. The solar cell according to claim 4, wherein the passivation layer comprises intrinsically amorphous silicon.

6. The solar cell according to claim 5, wherein the material of the metal layer is aluminium or an aluminium alloy.

7. The solar cell according to claim 6, wherein the material of the interlayer contains an aluminium-silicon alloy.

8. A method for production of a solar cell, comprising the steps of
a) applying discrete particles on a base layer of a semiconductor surface forming a solar cell
b) depositing a layer of a dielectric on regions of the base layer not covered by the particles
c) removing the particles
d) depositing a metal layer on the dielectric, and
e) producing an ohmic contact between the base layer and metal layer.

9. The method according to claim 6, wherein p-doped silicon is used as the material for the semiconductor surface.

10. The method according to claim 9, wherein a of applying a passivation layer on the base layer takes place before step a).

11. The method according to claim 10, wherein intrinsically amorphous silicon is used as the material for the passivation layer.

12. The method according to claim 9, wherein silicon nitride or silicon dioxide is used as the material for the dielectric.

13. The method according to claim 12, wherein the deposition of the dielectric takes place by PECVD processes, HWCVD processes, IAD processes or PVD processes.

14. The method according to claim 13, wherein the layer of dielectric has a thickness in the range from 10 to 500 nm.

15. The method according to claim 8, wherein the discrete particles comprise silicon dioxide.

16. The method according to claim 15, wherein the particles have a monomodal size distribution.

17. The method according to claim 16, wherein after deposition of the dielectric the particles are removed by mechanical action.

18. The method according to claim 8, wherein the material of the metal layer contains aluminium.

19. The method according to claim 18, wherein the metal layer has a thickness in the range from 0.5 to 10 μm.

20. The method according to claim 19, wherein the metal layer is applied by vapour deposition or sputtering.

21. The method according to claim 20, wherein the metal layer is sintered.
